(19) United States
(12) Patent Application Publication
(10) Pub. No.: US 2010/0263715 A1
(43) Pub. Date: Oct. 21, 2010

(54) Integrated Edge Clamping Mechanism for Processing of Laminates

(75) Inventors: Martin Wohlert, San Jose, CA (US); Pierluigi Lo-Menzo, Allariz (ES); Nicolas Barrois, Allariz (ES)

Correspondence Address: DIEHL SERVILLA LLC, 33 WOOD AVE SOUTH, SECOND FLOOR, SUITE 210, ISELIN, NJ, 08830, US

(73) Assignee: Applied Materials, Inc., Santa Clara, CA (US)

(21) Appl. No.: 12/425,857

(22) Filed: Apr. 17, 2009

(51) Int. Cl. H01L 31/048; B32B 37/06

(52) U.S. Cl. 136/251; 156/300

(57) ABSTRACT

Apparatuses, assemblies and methods for decreasing the frequency and severity of bubble defects in a photovoltaic module laminate. The apparatuses, assemblies and methods utilize at least one clamp having a plurality of grooves sized to apply pressure on the back surface of the glass substrate in the direction of the top glass layer and pressure on the top glass layer of the module directed toward the glass substrate to apply compressive force to the module without causing damage to the module.

### BACKGROUND

Embodiments of the present invention pertain to the lamination of photovoltaic modules. More specifically, embodiments pertain to assemblies and methods for laminating photovoltaic modules without bubble defects forming during autoclaving.

During the processing of photovoltaic modules it is often desirable to form a lamination including the photovoltaic cells protected between transparent panels. This lamination process may incorporate a layer of polyvinyl butyral (PVB) over the photovoltaic cells. The PVB layer helps seal the photovoltaic module laminate, protecting the photovoltaic cells from damage and exposure to the elements. A potential difficulty arises during the lamination process where bubbles or void can appear in the PVB interlayer at the edge or corners of the modules. If the bubbles are too large, or are open to the edge of the module, the bubbles will not be removed during the autoclave cycle, and potentially render the photovoltaic module unsuitable. These bubble defects can form as a result of trapped air in the PVB interlayer or from poor adhesion of the PVB film to the glass.

In non-solar glass applications, clamps may be used to apply pressure to the areas with bubbles to aid in sealing bubble defects. Binder clips, like those used in a normal business setting, are frequently employed for this purpose. The clamps are time consuming to apply by hand and can add undesirable stress concentrations in the laminate.

Therefore, there is a need in the art for apparatuses and methods to reduce or eliminate the bubble defects during the manufacture of photovoltaic modules. There is a need for apparatuses and methods which are quick and easy to apply without causing undue stress concentrations in the laminate.

### SUMMARY

Aspects of the present invention provide methods, apparatus and systems for decreasing the defects during lamination of photovoltaic modules. One or more embodiments of the invention are directed to assemblies comprising a plurality of photovoltaic modules standing on edge and having four corners and a thickness. Each module includes a glass substrate having a plurality of photovoltaic cells on a front surface, a back surface and an edge delete zone around the photovoltaic cells, a lamination layer of polyvinyl butyral over the front surface of the substrate and the photovoltaic cells and a top glass layer. The modules are held upright by at least one clamp having a plurality of grooves sized to apply pressure on the back surface of the glass substrate in the direction of the top glass layer and pressure on the top glass layer of the module directed toward the glass substrate to apply compressive force to the module without causing damage.

Other embodiments of the invention are directed to methods of processing a plurality of photovoltaic modules. A photovoltaic module is assembled having layers including a substrate having a back surface and a front surface, a plurality of photovoltaic cells on the front surface of the substrate with an edge delete zone surrounding the photovoltaic cells on the front surface, a lamination layer of polyvinyl butyral over the front surface of the substrate and the photovoltaic cells and a glass top over the lamination layer. A plurality of photovoltaic modules is assembled in at least one first clamp. The modules stand in an upright orientation. The plurality of modules have bottom edges and top edges. The bottom edges of the modules are held by the at least one first clamp. The at least one first clamp has a plurality of grooves sized to apply compressive force to the modules without causing damage. At least one second clamp is applied to the top edges of the plurality of modules. The at least one second clamp has grooves sized to apply compressive force to the modules without causing damage. The layers of the modules are laminated, while held in the clamps, in an autoclave.

### BRIEF DESCRIPTION OF THE DRAWINGS

FIG. 1 shows a cross-section of a photovoltaic module;

FIG. 2 shows a photograph of a bubble defect near the corner of a photovoltaic module;

FIG. 3 is a photograph of a stack of photovoltaic modules after lamination;

FIG. 4 shows a partial side view of a clamp rack for use in one or more embodiments of the invention;

FIG. 5 shows a partial side view of a clamp rack for use in one or more embodiments of the invention;

FIG. 6 shows a partial perspective view of a stack of photovoltaic modules separated by clamp racks in accordance with one or more embodiments of the invention; and

FIG. 7 shows a top view of a photovoltaic module in an array of clamps.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways.

Broad aspects of the invention are directed to racks which can be used to support the photovoltaic modules during the autoclave process. The racks are capable of applying pressure to the PVB interlayer to eliminate the voids or bubbles that may form. Depending on the location and type of defect, this can be accomplished with a flat surface which presses excess PVB into the edge of the modules. An alternative design uses a rack with slots or grooves which a photovoltaic module can sit in, causing pressure to be applied to the surface of the glass.

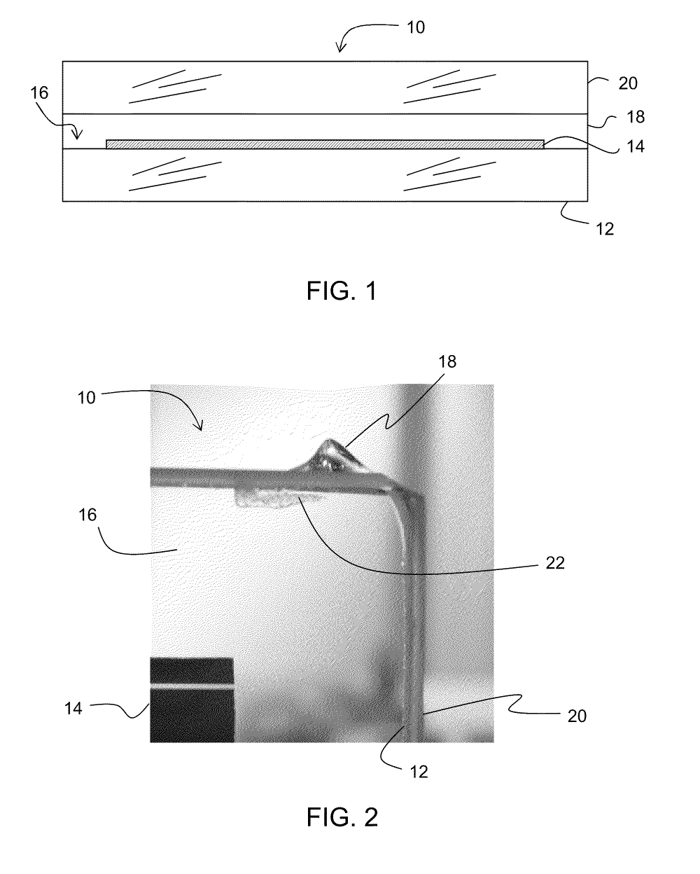

FIG. 1 shows a cross-section of a photovoltaic module laminate 10. The laminate 10 includes a substrate 12 which has a series of photovoltaic cells 14 thereon. The substrate 12 is commonly made of glass, but other materials can be employed. An edge delete zone 16 is created around the photovoltaic cells 14, exposing the substrate 12. The edge delete zone 16 is typically about 50 μm below the top surface of the photovoltaic cells 14. An interlayer of polyvinyl butyral 18 is applied to the photovoltaic cell 14 side of the substrate 12 and a piece of glass 20, or other suitable material, is on top of the PVB interlayer 18. This combination of components—substrate 12, photovoltaic cells 14, PVB interlayer 18 and top layer 20—make up a photovoltaic module.

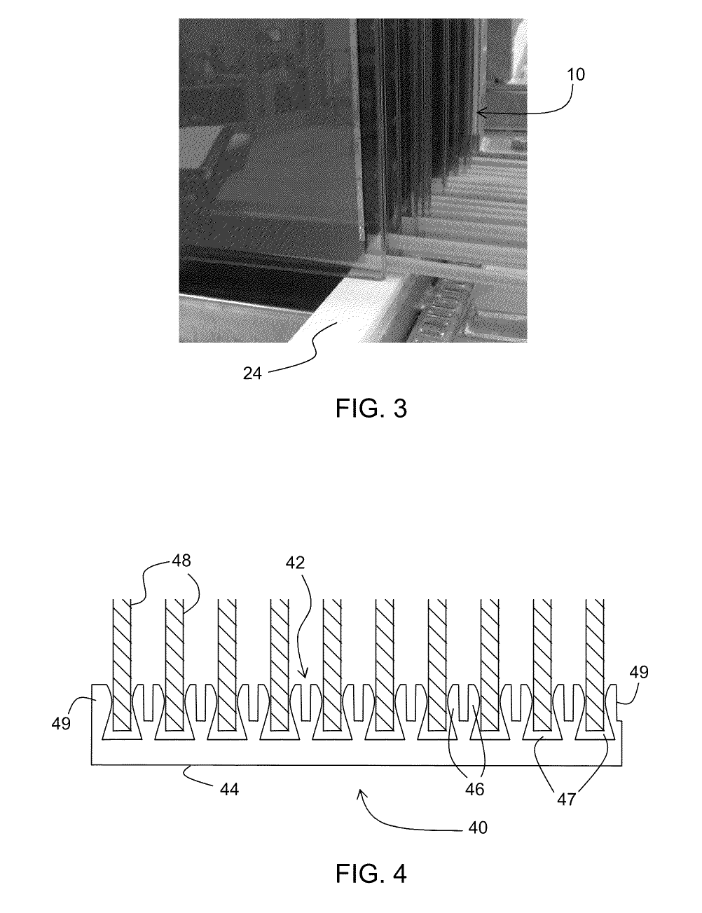

FIG. 2 shows a photovoltaic module 10 with an edge defect 22, sometimes referred to herein as bubbles. The substrate 12, photovoltaic cells 14, edge delete zone 16, PVB interlayer 18 and top layer 20 can be seen. The PVB interlayer 18 has been squeezed out of module 10 resulting in an undesirable defect. FIG. 3 shows a stack of photovoltaic modules 10 with the corners supported by a Teflon® rack 24. The rack 24 holds the laminates during autoclave processing, and these modules 10 do not show corner defects like that in FIG. 2. The pressure from the weight of the modules 10 resting on the rack 24 helps force PVB into the voids so they are sealed during the autoclave process. Without being bound by any particular theory of operation, it is believed that applying pressure only along the bottom edge of the laminates minimizes stress concentrations. However, application of clamping pressure to the top, bottom or sides of the laminates may be desirable as well.

In a broad sense, embodiments of the invention include racks or supports having a slot, or groove, which would hold the laminates during processing. Depending on the dimensions of the groove (width and side wall angle), the amount of pressure applied to the surface of the laminates could be controlled. The application of pressure to the surface of the laminate has the potential to remove a much greater range of defects. However, there is a risk that stress concentrations may be formed in the laminate as it cools with pressure applied to specific regions. A major advantage of the apparatus, assemblies and methods described herein is that clamping of specific locations on every panel can be automated such that the modules are placed into the rack without the need for an operator to manually place a clamp on the corners of each of the laminates.

FIG. 4 shows a clamp rack 40 according tone or more embodiments of the invention. The clamp rack 40 includes a plurality of slotted or bifurcated projections 42 attached to a main body 44 and laterally spaced from each other to provide grooves 47 sized to receive photovoltaic modules 48. The slotted projections 42 can have two contacting surfaces 46 to grip the photovoltaic modules 48. The contacting surfaces 46 are spaced apart from each other for a distance suitable to provide clamping pressure to the modules without damaging the modules 48. Thus, the grooves 47 have width based on a the width of the photovoltaic modules they are designed to hold, the width of the grooves being sized to apply pressure on the back surface of the glass substrate in the direction of the top glass layer and pressure on the top glass layer of the module directed toward the glass substrate to apply compressive force to the module without causing damage. The end holders 49 may only have a single contacting surface 46. The end holders 49, and the end of the main body 44 can be shaped to cooperatively interact with adjoining racks 40 to allow for optimum usage of space within the autoclave. The contacting surfaces 46 are shown holding the modules 48 at a distance slightly inward of the module ends, but the location of contact can be changed based on the desired results. The modules 48 are illustrated hovering above the main body 44 but the modules 48 could rest on the main body 44 is desired. It will be appreciated that in use, when a module 48 is mounted into a groove 47, the slotted projections 42 permit compression of the projection as the module 48 is pushed into the groove, but the slotted projections have sufficient rigidity to provide adequate holding and compressive force of the modules 48 by the contacting surfaces 46.

The contacting surfaces 46 of the rack 40 may have a coating (not shown) or be integrally formed with the main body 44. The rack 40 is designed so that the contacting surfaces 46 apply pressure to each side of the modules 48. It is possible that racks 40 according to FIG. 4 would be used exclusively for a specific thickness of module 48. Therefore, a number of different racks 40 having different spacing between the contacting surfaces 46 and/or spacing between the holders 42 can be employed depending on the size of the module 48 and the desired pressure requirements.

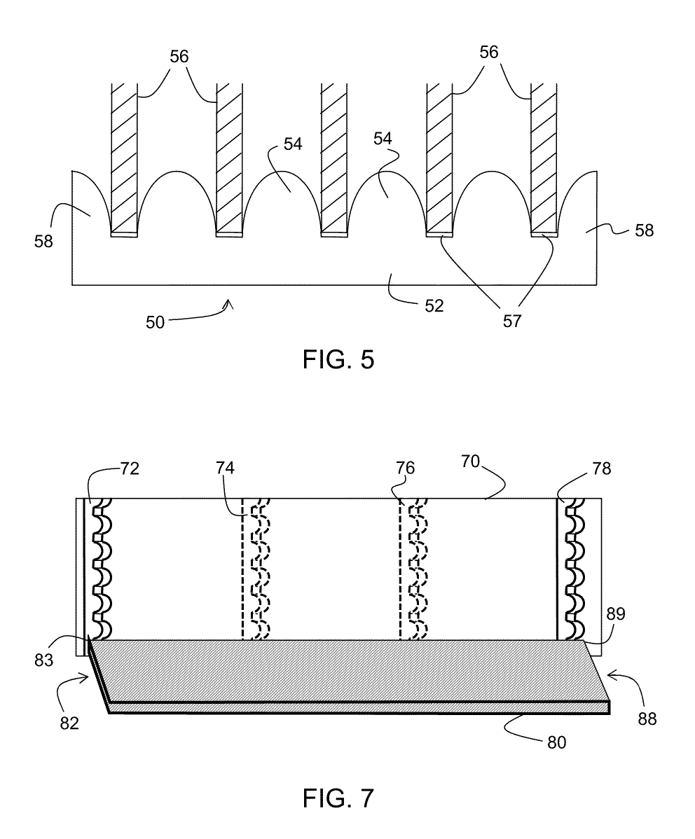

FIG. 5 shows a clamp rack 50 according to, and for use with, various embodiments of the invention. The clamp rack 50 is made up of a body 52 and a plurality of projections 54 in a spaced apart relation to provide grooves 57. As with the embodiment described above, the grooves 57 are sized to apply pressure on the back surface of the glass substrate in the direction of the top glass layer and pressure on the top glass layer of the module directed toward the glass substrate to apply compressive force to the module without causing damage. In the embodiment shown in FIG. 5, the projections 54 are elliptical in shape, which facilitates loading of modules 56 into the grooves 57. It will be understood of course, that the projections 54 can be any suitable shape. The projections 54 can be integrally formed with the body 52, or made of a different material and affixed to the body 52. Additionally, the projections 54 can have a coating (not shown) to provide, for example, different frictional properties than the body 52. Each projection 54 may be shaped to contact two photovoltaic modules 56. The end holders 58 may be shaped to contact a single photovoltaic module 56, but can also have surface features (not shown) for cooperatively interacting with adjacent racks 50. The projections 54 shown in FIG. 5 have a rounded shape without straight sides, but other shapes can be used. The advantage to this projection 54 is that modules 56 with different thickness can be employed by a single size rack 50. The spacing between the projection 54 can be modified to permit more or less distance between adjacent modules 56.

The racks shown in FIGS. 4 and 5 are merely indicative of specific shapes and should not be taken as limiting the invention. Other shapes and designs are contemplated and remain within the scope of the invention.

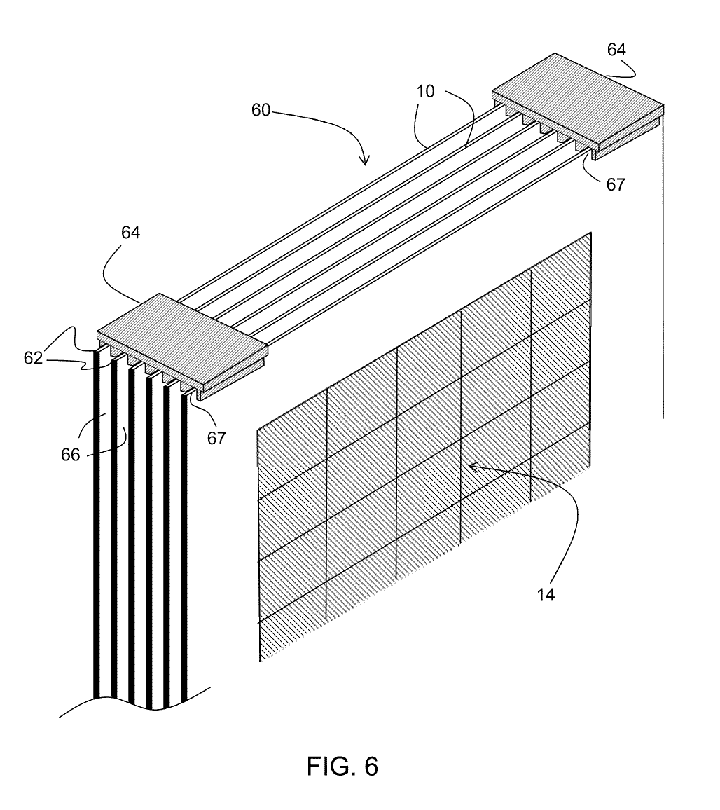

With reference to FIGS. 1 and 6, one or more embodiments of the invention are directed to assemblies 60 comprising a plurality of photovoltaic modules 10 standing on edge. Each module 10 can have four corners 62, i.e., being square or rectangular in shape, but other shapes could be employed. Each module 10 includes a glass substrate 12, or other suitable material, having a plurality of photovoltaic cells 14 on a front surface, a back surface and an edge delete zone 16 around the photovoltaic cells 14. A lamination layer 18 of polyvinyl butyral is over the front surface of the substrate 12 and the photovoltaic cells 14 and a top glass layer 20 is over the lamination layer 18. The modules 10 are spaced apart, leaving a gap 66, and held upright by at least one clamp 64 having a plurality of grooves sized to apply pressure on the back surface of the glass substrate in the direction of the top glass layer and pressure on the top glass layer of the module directed toward the glass substrate. The clamp 64 has grooves 67 sized to apply compressive force to the modules 10 without causing damage. The gap permits hot air in the autoclave to circulate between the module laminates.

The gap 66 of various embodiments is equal to about the thickness of the modules 10. The thickness of the modules 10 are generally within the range of about 4 mm to about 10 mm. In specific embodiments, the thickness of the modules 10 and/or the gap 66 is about 9, 8, 7, 6 or 5 mm.

According to some embodiments, the clamps 64 can apply pressure to the photovoltaic modules 10 at a plurality of points. In a specific embodiment, as shown in FIG. 6, clamps apply pressure to at least the corners of the photovoltaic modules 10.

FIG. 7 shows an embodiment including an array of clamps 72, 74, 76, 78 of the type described with respect to FIG. 5 comprising a clamp body 70. Here, clamp body 70 is includes a first clamp 72 and a second clamp 78 in a spaced apart relationship so that the clamps 72 and 78 can hold module 80 at or adjacent ends of the module 82 and 88. When positioned adjacent the ends 82 and 88 of the module 80, clamps 72 and 78 hold the module 80 by corners 83 and 89. Clamps 74 and 76 (shown in phantom) can be provided at locations intermediate the ends 82 and 88 of the modules to provide stability in holding the modules 80. It will be appreciates that each of the clamps 72, 74, 76 and 78 can be separate pieces that are attached to clamp body 70, or alternatively, one or more of the clamps 72, 74, 76, and 78 can be integrally formed with the clamp body 70. As described above with respect to FIGS. 5 and 6, each of the clamps has laterally spaced grooves sized to apply pressure on the back surface of the glass substrate in the direction of the top glass layer and pressure on the top glass layer of the module directed toward the glass substrate to apply compressive force to the module without causing damage to the module.

Additional embodiments of the invention are directed to methods of processing a plurality of photovoltaic modules. A photovoltaic module 10, as shown in FIG. 1, is assembled including a substrate 12 having a back surface and a front surface, a plurality of photovoltaic cells 14 on the front surface of the substrate 12 with an edge delete zone 16 surrounding the photovoltaic cells 14 on the front surface. A lamination layer 18 of polyvinyl butyral is over the front surface of the substrate 12 and the photovoltaic cells 14. A glass top 20, or other suitable material, is over the lamination layer 18. A plurality of photovoltaic modules are assembled in at least one first clamp. The modules stand in an upright orientation. The plurality of modules have bottom edges and top edges. The bottom edges of the modules are held by the at least one first clamp. The at least one first clamp has a plurality of grooves sized to apply compressive force to the modules without causing damage. At least one second clamp is applied to the top edges of the plurality of modules. The at least one second clamp is has grooves sized to apply compressive force to the modules without causing damage. The layers of the modules held by the clamp are laminated in an autoclave.

The photovoltaic modules of some embodiments are spaced so that the front surface of one module does not contact the back surface of an adjacent module. The space between the photovoltaic modules can be any suitable spacing, but in a detailed embodiment, the space is equal to about the thickness of the photovoltaic modules.

According to some specific embodiments, the at least one first clamp applies pressure a plurality of points on the photovoltaic module, as shown in FIG. 7. The plurality of points can include the corners of the photovoltaic modules and may include strategically placed locations between the corners.

The first clamp and/or second clamp may comprise a single clamp structure having a plurality of grooves which engage the photovoltaic modules. The grooves can be spaced so that the corners and/or strategically placed areas between the corners are clamped.

Although the invention herein has been described with reference to particular embodiments, it is to be understood that these embodiments are merely illustrative of the principles and applications of the present invention. It will be apparent to those skilled in the art that various modifications and variations can be made to the method of the present invention without departing from the spirit and scope of the invention. Thus, it is intended that the present invention include modifications and variations that are within the scope of the appended claims and their equivalents.

1. An assembly comprising:
a plurality of photovoltaic modules standing on edge and having four corners and a thickness, each module including a glass substrate having a plurality of photovoltaic cells on a front surface, a back surface and an edge delete zone around the photovoltaic cells, a lamination layer of polyvinyl butyral over the front surface of the substrate and the photovoltaic cells and a top glass layer, the modules held upright by at least one clamp having a plurality of grooves sized to apply pressure on the back surface of the glass substrate in the direction of the top glass layer and pressure on the top glass layer of the module directed toward the glass substrate to apply compressive force to the module without causing damage to the module.

2. The assembly of claim 1, wherein there is a gap between each of the plurality of photovoltaic modules.

3. The assembly of claim 2, wherein the gap between the modules is equal to about the thickness of the modules.

4. The assembly of claim 3, wherein the thickness of the photovoltaic modules and the gap between the modules is in the range of about 4 mm to about 10 mm.

5. The assembly of claim 3, wherein the thickness of the photovoltaic modules and the gap between the modules is about 7 mm.

6. The assembly of claim 1, wherein the at least one clamp applies pressure to the photovoltaic modules at a plurality of points.

7. The assembly of claim 6, wherein the at least one clamp applies pressure to at least the corners of the photovoltaic modules.

8. The assembly of claim 1, wherein the assembly includes a single clamp.

9. The assembly of claim 1, wherein there are at least two clamps providing pressure to the four corners of the photovoltaic module.

10. The assembly of claim 1, wherein the grooves are provided by laterally spaced projections laterally spaced apart on a main body.

11. The assembly of claim 10, wherein the projections are slotted projections defining two contacting surfaces that contact a module surface.

12. The assembly of claim 10, wherein the projections are elliptical in shape.

13. A method of processing a plurality of photovoltaic modules comprising:
assembling a photovoltaic module having layers including a substrate having a back surface and a front surface, a plurality of photovoltaic cells on the front surface of the substrate with an edge delete zone surrounding the photovoltaic cells on the front surface, a lamination layer of polyvinyl butyral over the front surface of the substrate and the photovoltaic cells and a glass top over the lamination layer;
assembling a plurality of photovoltaic modules in a first clamp, the modules standing in an upright orientation, the plurality of modules having bottom edges and top edges, the bottom edges of the modules held by the first clamp, the at least one first clamp having a plurality of grooves sized to apply compressive force to the modules without causing damage;
applying a second clamp to the top edges of the plurality of modules, the at least one second clamp having grooves sized to apply compressive force to the modules without causing damage; and
laminating the layers of the modules held in the clamps in an autoclave.

14. The method of claim 13, wherein the grooves of the first and second clamps are spaced so that the front surface of one module does not contact the back surface of an adjacent module.

15. The method of claim 14, wherein the space between the grooves is equal to about the thickness of the photovoltaic modules.

16. The method of claim 13, wherein each of the grooves of the first clamp applies pressure to a plurality of points on each photovoltaic module.

17. The method of claim 16, wherein the plurality of points includes the corners of each photovoltaic module.

18. The method of claim 13, wherein the grooves of the first clamp are defined by contacting surfaces engaging the photovoltaic modules.

19. The method of claim 13, wherein the second clamp comprises a plurality of grooves, the grooves engaging the photovoltaic modules.

20. The method of claim 13, where the first clamp and the second clamp are associated with a clamp body for holding the photovoltaic modules.
